(19) United States
(12) Patent Application Publication
(10) Pub. No.: US 2013/0113118 A1
(43) Pub. Date: May 9, 2013

(54) Semiconductor Device and Method of Forming Sloped Surface in Patterning Layer to Separate Bumps of Semiconductor Die from Patterning Layer

(71) Applicants: MinJung Kim, Kyounggi-do (KR); JoungIn Yang, Seoul (KR); DaeSik Choi, Seoul (KR); KyungEun Kim, Kyounggi-do (KR)

(72) Inventors: MinJung Kim, Kyounggi-do (KR); JoungIn Yang, Seoul (KR); DaeSik Choi, Seoul (KR); KyungEun Kim, Kyounggi-do (KR)

(73) Assignee: STATS CHIPPAC, LTD., Singapore (SG)

(21) Appl. No.: 13/289,811

(22) Filed: Nov. 4, 2011

(51) Int. Cl. H01L 23/48; H01L 21/58

(52) U.S. Cl. 257/782; 438/121; 257/E23.06; 257/E21.505

(57) ABSTRACT

A semiconductor device has a semiconductor die with bumps formed over a surface of the semiconductor die. A conductive layer is formed over a substrate. A patterning layer is formed over the substrate and conductive layer. A masking layer having an opaque portion and linear gradient contrast portion is formed over the patterning layer. The linear gradient contrast portion transitions from near transparent to near opaque. The patterning layer is exposed to ultraviolet light through the masking layer. The masking layer is removed and a portion of the patterning layer is removed to form an opening having a sloped surface to expose the conductive layer. The sloped surface in patterning layer can be formed by laser direct ablation. The semiconductor die is mounted to the substrate with the bumps electrically connected to the conductive layer and physically separated from the patterning layer.

### FIELD OF THE INVENTION

The present invention relates in general to semiconductor devices and, more particularly, to a semiconductor device and method of forming a sloped surface in a patterning layer to physically separate bumps of a semiconductor die from the patterning layer.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly can refer to both a single semiconductor device and multiple semiconductor devices.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller semiconductor die size can be achieved by improvements in the front-end process resulting in semiconductor die with smaller, higher density active and passive components. Back-end processes may result in semiconductor device packages with a smaller footprint by improvements in electrical interconnection and packaging materials.

A conventional semiconductor package may contain a semiconductor die mounted to a substrate. A conductive interconnect structure, such as conductive bumps, is formed over the semiconductor die. A conductive layer is formed over a surface of the substrate for mating to the bumps. A patterning layer is formed over the conductive layer and surface of the substrate. A portion of the patterning layer is removed to form openings and expose the conductive layer. The openings in the patterning layer typically have abrupt edges. The semiconductor die is mounted to the substrate with the bumps electrically and metallurgically connected to the conductive layer on the substrate. The bumps also physical contact the edges of the patterning layer. The physical contact between the bumps and patterning layer induces stress on the bumps and conductive layer, particularly during thermal and other reliability testing. The stress on the bumps and conductive layer leads to cracking and other stress-induced damage on the interconnect structure between the semiconductor die and substrate during the manufacturing process.

### SUMMARY OF THE INVENTION

A need exists to reduce stress on the interconnect structure between the semiconductor die and substrate during the manufacturing process. Accordingly, in one embodiment, the present invention is a method of making a semiconductor device comprising the steps of providing a semiconductor die, forming a plurality of bumps over a surface of the semiconductor die, providing a substrate, forming a first conductive layer over the substrate, forming a patterning layer over the substrate and first conductive layer, disposing a masking layer having an opaque portion and gradient contrast portion over the patterning layer, exposing the patterning layer to ultraviolet light through the masking layer, removing the masking layer, removing a portion of the patterning layer to form an opening having a sloped surface to expose the first conductive layer, and mounting the semiconductor die to the substrate with the bumps electrically connected to the first conductive layer and physically separated from the patterning layer.

In another embodiment, the present invention is a method of making a semiconductor device comprising the steps of providing a semiconductor die, forming an interconnect structure over a surface of the semiconductor die, providing a substrate, forming a first conductive layer over the substrate, forming a patterning layer over the substrate and first conductive layer, forming an opening having a sloped surface in the patterning layer to expose the first conductive layer, and mounting the semiconductor die to the substrate with the interconnect structure electrically connected to the first conductive layer and separated from the patterning layer.

In another embodiment, the present invention is a method of making a semiconductor device comprising the steps of providing a substrate, forming a first conductive layer over the substrate, forming a patterning layer over the substrate and first conductive layer, and forming an opening having a sloped surface in the patterning layer to expose the first conductive layer.

In another embodiment, the present invention is a semiconductor device comprising a substrate and first conductive layer formed over the substrate. A patterning layer is formed over the substrate and first conductive layer. An opening having a sloped surface is formed in the patterning layer to expose the first conductive layer.

### BRIEF DESCRIPTION OF THE DRAWINGS

FIG. 1 illustrates a printed circuit board with different types of packages mounted to its surface;

FIGS. 2a-2c illustrate further detail of the representative semiconductor packages mounted to the printed circuit board;

FIGS. 3a-3c illustrate a semiconductor wafer with a plurality of semiconductor die separated by a saw street; and

FIGS. 4a-4k illustrate a process of forming a sloped surface in a patterning layer to physically separate bumps of a semiconductor die from the patterning layer.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, the negative photoresist, is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Patterning is the basic operation by which portions of the top layers on the semiconductor wafer surface are removed. Portions of the semiconductor wafer can be removed using photolithography, photomasking, masking, oxide or metal removal, photography and stenciling, and microlithography. Photolithography includes forming a pattern in reticles or a photomask and transferring the pattern into the surface layers of the semiconductor wafer. Photolithography forms the horizontal dimensions of active and passive components on the surface of the semiconductor wafer in a two-step process. First, the pattern on the reticle or masks is transferred into a layer of photoresist. Photoresist is a light-sensitive material that undergoes changes in structure and properties when exposed to light. The process of changing the structure and properties of the photoresist occurs as either negative-acting photoresist or positive-acting photoresist. Second, the photoresist layer is transferred into the wafer surface. The transfer occurs when etching removes the portion of the top layers of semiconductor wafer not covered by the photoresist. The chemistry of photoresists is such that the photoresist remains substantially intact and resists removal by chemical etching solutions while the portion of the top layers of the semiconductor wafer not covered by the photoresist is removed. The process of forming, exposing, and removing the photoresist, as well as the process of removing a portion of the semiconductor wafer can be modified according to the particular resist used and the desired results.

In negative-acting photoresists, photoresist is exposed to light and is changed from a soluble condition to an insoluble condition in a process known as polymerization. In polymerization, unpolymerized material is exposed to a light or energy source and polymers form a cross-linked material that is etch-resistant. In most negative resists, the polymers are polyisopremes. Removing the soluble portions (i.e. the portions not exposed to light) with chemical solvents or developers leaves a hole in the resist layer that corresponds to the opaque pattern on the reticle. A mask whose pattern exists in the opaque regions is called a clear-field mask.

In positive-acting photoresists, photoresist is exposed to light and is changed from relatively nonsoluble condition to much more soluble condition in a process known as photosolubilization. In photosolubilization, the relatively insoluble resist is exposed to the proper light energy and is converted to a more soluble state. The photosolubilized part of the resist can be removed by a solvent in the development process. The basic positive photoresist polymer is the phenol-formaldehyde polymer, also called the phenol-formaldehyde novolak resin. Removing the soluble portions (i.e. the portions exposed to light) with chemical solvents or developers leaves a hole in the resist layer that corresponds to the transparent pattern on the reticle. A mask whose pattern exists in the transparent regions is called a dark-field mask.

After removal of the top portion of the semiconductor wafer not covered by the photoresist, the remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual semiconductor die and then packaging the semiconductor die for structural support and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

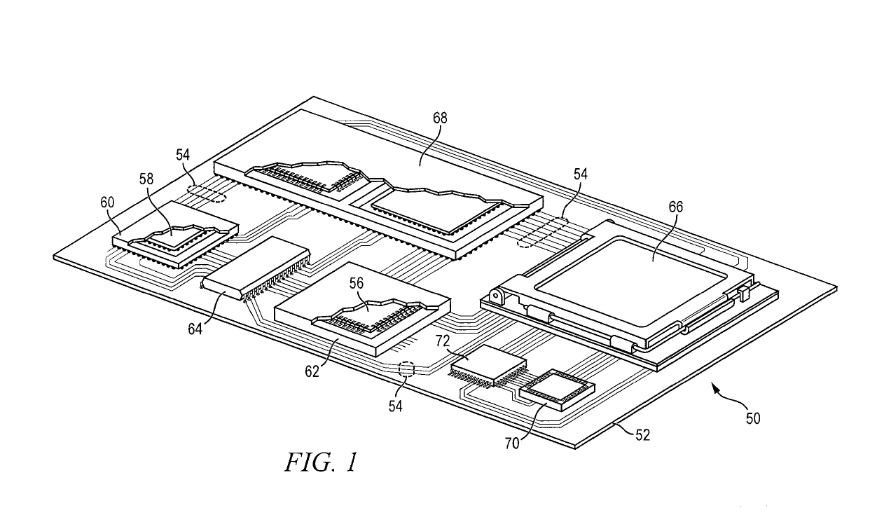

FIG. 1 illustrates electronic device 50 having a chip carrier substrate or printed circuit board (PCB) 52 with a plurality of semiconductor packages mounted on its surface. Electronic device 50 can have one type of semiconductor package, or multiple types of semiconductor packages, depending on the application. The different types of semiconductor packages are shown in FIG. 1 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for these products to be accepted by the market. The distance between semiconductor devices must be decreased to achieve higher density.

In FIG. 1, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

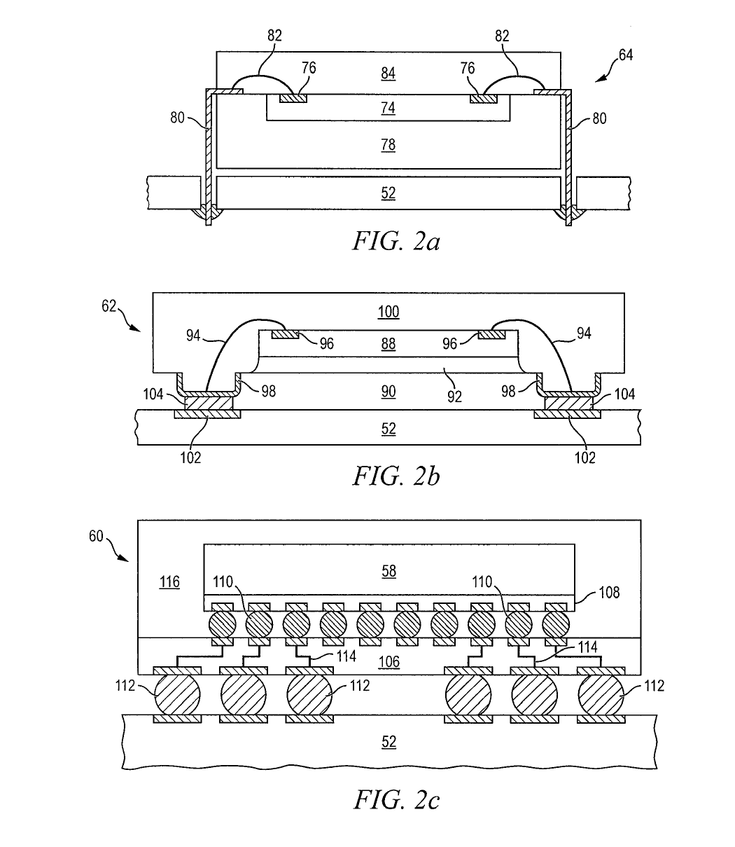

FIGS. 2a-2c show exemplary semiconductor packages. FIG. 2a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit can include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and bond wires 82 provide electrical interconnect between semiconductor die 74 and PCB 52. Encapsulant 84 is deposited over the package for environmental protection by preventing moisture and particles from entering the package and contaminating semiconductor die 74 or bond wires 82.

FIG. 2b illustrates further detail of BCC 62 mounted on PCB 52. Semiconductor die 88 is mounted over carrier 90 using an underfill or epoxy-resin adhesive material 92. Bond wires 94 provide first level packaging interconnect between contact pads 96 and 98. Molding compound or encapsulant 100 is deposited over semiconductor die 88 and bond wires 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 2c, semiconductor die 58 is mounted face down to intermediate carrier 106 with a flipchip style first level packaging. Active region 108 of semiconductor die 58 contains analog or digital circuits implemented as active devices, passive devices, conductive layers, and dielectric layers formed according to the electrical design of the die. For example, the circuit can include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flipchip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flipchip style first level packaging without intermediate carrier 106.

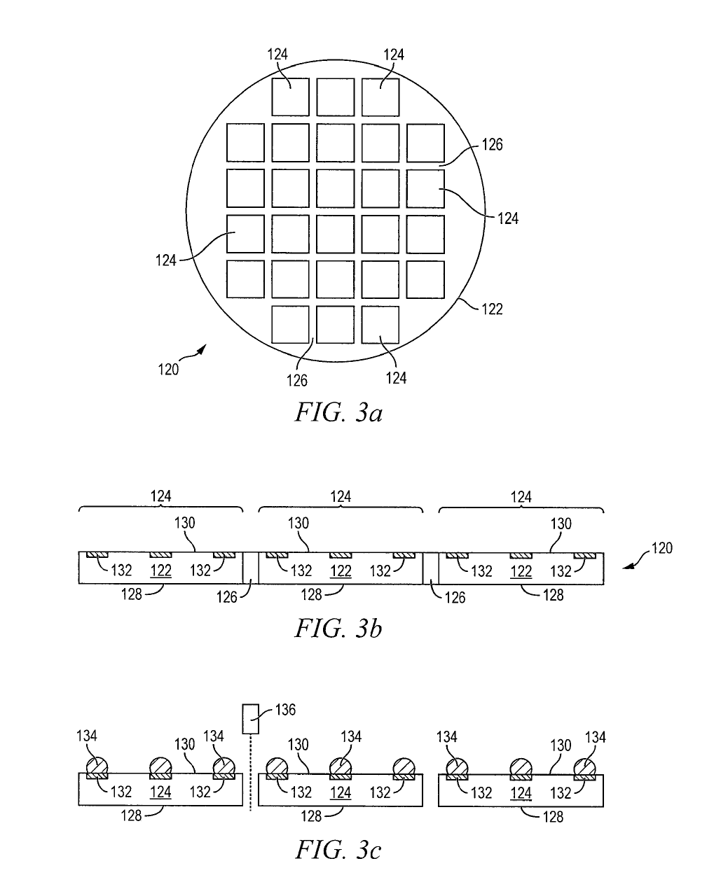

FIG. 3a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by a non-active, inter-die wafer area or saw street 126 as described above. Saw street 126 provides cutting areas to singulate semiconductor wafer 120 into individual semiconductor die 124.

FIG. 3b shows a cross-sectional view of a portion of semiconductor wafer 120. Each semiconductor die 124 has a back surface 128 and active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing. In one embodiment, semiconductor die 124 is a flipchip type device.

An electrically conductive layer 132 is formed over active surface 130 using PVD, CVD, electrolytic plating, electroless plating process, or other suitable metal deposition process. Conductive layer 132 can be one or more layers of Al, Cu, Sn, Ni, Au, Ag, or other suitable electrically conductive material. Conductive layer 132 operates as contact pads electrically connected to the circuits on active surface 130. Contact pads 132 can be disposed side-by-side a first distance from the edge of semiconductor die 124, as shown in FIG. 3b. Alternatively, contact pads 132 can be offset in multiple rows such that a first row of contact pads is disposed a first distance from the edge of the die, and a second row of contact pads alternating with the first row is disposed a second distance from the edge of the die.

In FIG. 3c, an electrically conductive bump material is deposited over conductive layer 132 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 132 using a suitable attachment or bonding process. In one embodiment, the bump material is reflowed by heating the material above its melting point to form balls or bumps 134. In some applications, bumps 134 are reflowed a second time to improve electrical contact to conductive layer 132. Bumps 134 can also be compression bonded to conductive layer 132. Bumps 134 represent one type of interconnect structure that can be formed over conductive layer 132. The interconnect structure can also use stud bump, micro bump, or other electrical interconnect.

Semiconductor wafer 120 is singulated saw street 126 with saw blade or laser cutting tool 136 into individual semiconductor die 124.

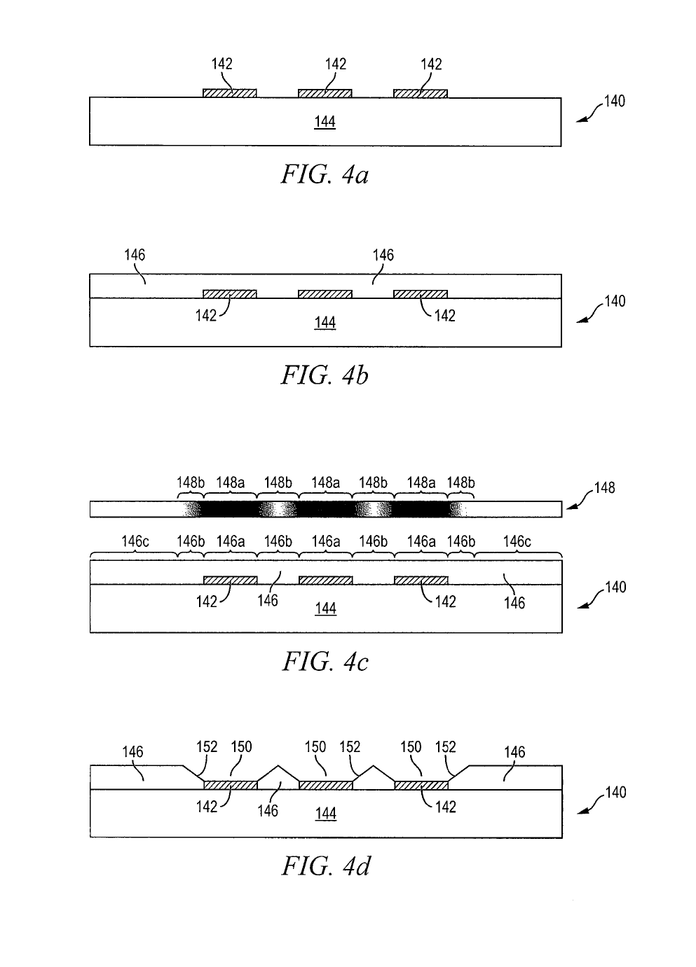

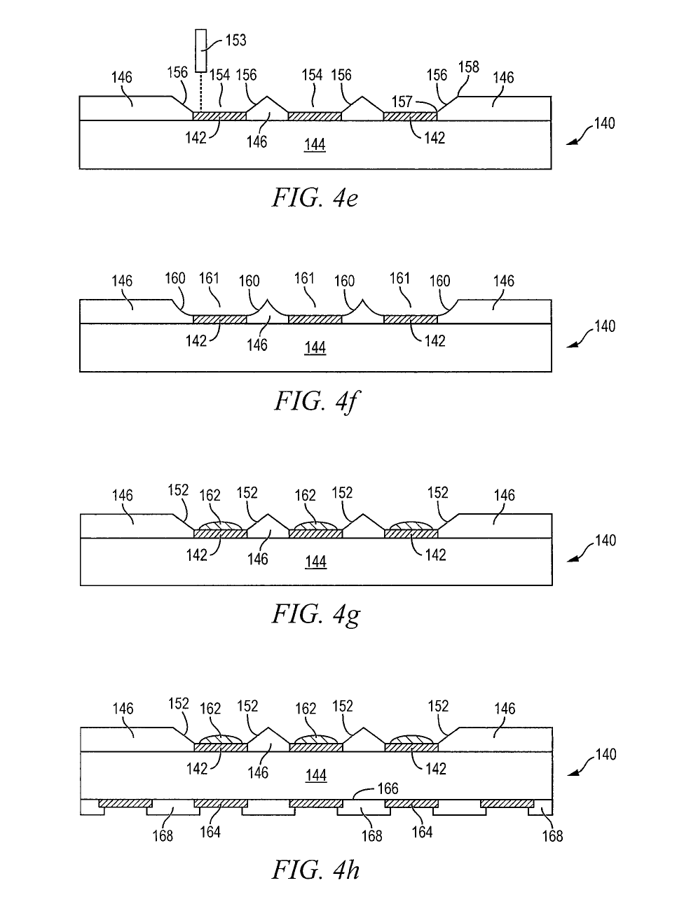

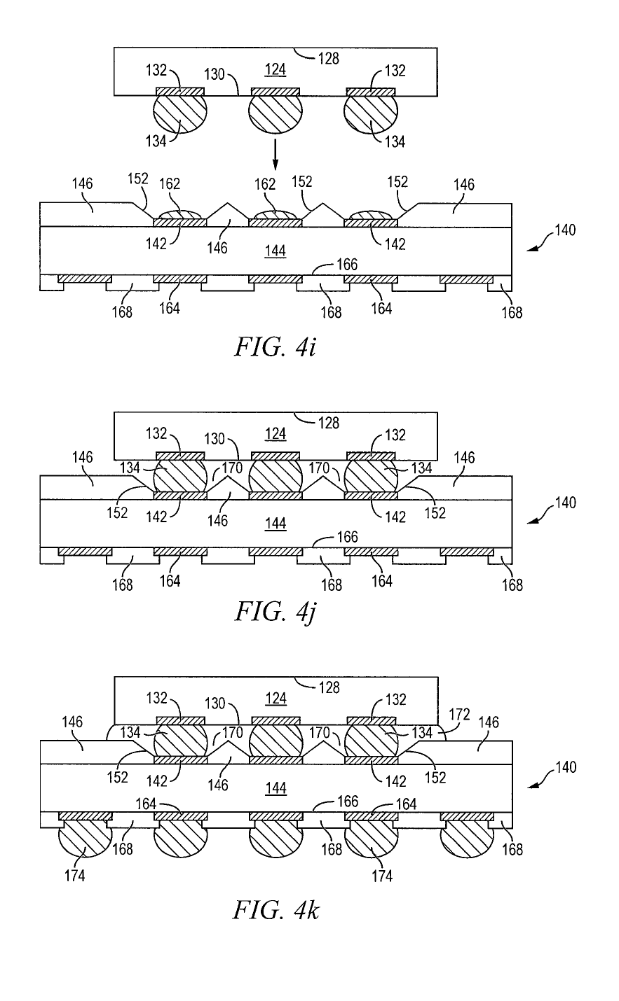

FIGS. 4a-4k illustrate, in relation to FIGS. 1 and 2a-2c, a process of forming a sloped surface in a patterning layer to physically separate bumps of a semiconductor die from the patterning layer. FIG. 4a shows a substrate or PCB 140 suitable for mounting semiconductor die 124. Substrate 140 contains one or more conductive layers 142 formed on laminated insulating or dielectric layers 144. Substrate 140 can be silicon, germanium, gallium arsenide, indium phosphide, silicon carbide, polymer, beryllium oxide, or other suitable rigid material for structural support. Alternatively, insulating layers 144 can be one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Conductive layer 142 can be one or more layers of Al, Cu, Sn, Ni, Au, Ag, or other suitable electrically conductive material formed by electrolytic plating or electroless plating for electrical interconnect. The layout of conductive layer 142 and insulating layers 144 typically uses silk screen printing, photoengraving, PCB milling, electroless plating, or electroplating process.

In FIG. 4b, a patterning or photoresist layer 146 is formed over substrate 140 and conductive layer 142 using printing, spin coating, or spray coating. In one embodiment, patterning layer 146 is a dry film photoresist lamination with a thickness of 10-60 micrometers (μm). In other embodiments that utilize an insulating layer for patterning, the insulating layer can include one or more layers of SiO2, Si3N4, SiON, Ta2O5, Al2O3, or other material having similar structural properties.

In FIG. 4c, a masking layer 148 is disposed over substrate 140. Masking layer 148 has a solid or opaque portion 148a disposed over conductive layer 142, and a linear gradient contrast portion 148b disposed over portion 146b of photoresist layer 146 adjacent to conductive layer 142. More specifically, linear gradient contrast portion 148b transitions from near transparent characteristics to near opaque characteristics across the linear gradient contrast. The near opaque characteristic of linear gradient contrast portion 148b is disposed adjacent to opaque portion 148a. The near transparent characteristic of linear gradient contrast portion 148b is disposed over a portion of photoresist layer 146 midway between conductive layers 142. Accordingly, masking layer 148 transitions from opaque to near opaque to near transparent to near opaque to opaque across one section of opaque portion 148a and linear gradient contrast portion 148b. The pattern of alternating opaque portion 148a and linear gradient contrast portion 148b is repeated across adjacent conductive layers 142.

Masking layer 148 over photoresist layer 146 is exposed to ultraviolet (UV) light. Photoresist layer 146 is cured at varying rates depending on the intensity of the UV light incident to the surface of the photoresist layer. The transition from near opaque to near transparent to near opaque across linear gradient contrast portion 148b passes UV light with linearly varying intensity. The near transparent portion of 148b passes near maximum UV light. The UV light intensity incident to photoresist layer 146 decreases from the near transparent portion of 148b to the near opaque portion of 148b and is blocked below opaque portion 148a. The portion 146c of photoresist layer 146 receives maximum UV light and is completely cured. The cure rate of photoresist layer 146, in response to the relative penetration of the UV light across linear gradient contrast portion 148b, begins to decrease below the near transparent portion of 148b and linearly decreases across portion 146b of photoresist layer 146 to the region below the near opaque portion of 148b. The portion 146b of photoresist layer 146 exhibits a linear gradient cured state. The portion 146a of photoresist layer 146 below opaque portion 148a is not cured by the UV light.

In FIG. 4d, masking layer 148 is removed and photoresist layer 146 is subjected to an etching and rinsing process. The portion 146c of photoresist layer 146 remains in place during etching because of its completely cured state. The portion 146b of photoresist layer 146 is partially removed according to its linear gradient cured state leaving a slanted opening 150 defined by sloped surface 152. In one embodiment, the sloped surface 152 of photoresist layer 146 has a 20-50 degree grade. The portion 146a of photoresist layer 146 below opaque portion 148a is completely removed due its non-cured state to expose conductive layer 142.

In another embodiment continuing from FIG. 4b, a portion of photoresist layer 146 is removed by laser direct ablation (LDA) using laser 153, as shown in FIG. 4e. In particular, the intensity or duration of laser 153 is controlled to create a gradual slanted opening 154 defined by linear sloped surface 156 in photoresist layer 146. The gradual linear sloped surface 156 extends from point 157 adjacent to conductive layer 142 to point 158 on a surface of photoresist layer 146. Photoresist layer 146 is completely removed over a portion of conductive layer 142 with laser 153. In one embodiment, the gradual sloped surface 156 of photoresist layer 146 from point 157 to point 158 has a 20-50 degree grade. The removed portion of photoresist layer 146 across conductive layer 142 and the sloped surfaces 152 on either side of the conductive constitute gradual slanted opening 154 in photoresist layer 146.

FIG. 4f shows an embodiment with a non-linear sloped surface 160 formed in opening 161 of photoresist layer 146. The sloped surface 160 can be concave or convex. The non-linear sloped surface 160 can be formed by a non-linear gradient contrast portion 148b or by laser 153.

Continuing from FIG. 4d, a conductive paste or flux material 162 is deposited by screen printing over conductive layer 142, as shown in FIG. 4g. Conductive paste 162 aids with the union between bumps 134 and conductive layer 142.

In FIG. 4h, an electrically conductive layer 164 is formed over surface 166 of substrate 140 opposite conductive layer 142 using a patterning and metal deposition process, such as PVD, CVD, electrolytic plating, or electroless plating process. Conductive layer 164 can be one or more layers of Al, Cu, Sn, Ni, Au, Ag, or other suitable electrically conductive material. Conductive layer 164 operates as RDL and contacts pads for bump formation. Conductive layer 164 is electrically connected through substrate 140 to conductive layer 142.

An insulating or passivation layer 168 is formed over surface 166 of substrate 140 and conductive layer 164 using PVD, CVD, printing, spin coating, spray coating, sintering or thermal oxidation. The insulating layer 168 contains one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. A portion of insulating layer 168 is removed by an etching process through a patterned photoresist layer to expose conductive layer 164. A portion of conductive layer 164 remains covered by insulating layer 168.

In FIG. 4i, semiconductor die 124 from FIGS. 3a-3c is positioned over and mounted to substrate 140 using a pick and place operation with active surface 130 oriented toward the substrate and bumps 134 aligned with conductive paste 162 disposed over conductive layer 142. FIG. 4j shows semiconductor die 124 mounted to substrate 140 with bumps 134 electrically and metallurgically connected to conductive paste 162 and conductive layer 142. The sloped surface 152 of photoresist layer 146 provides a gap 170 to avoid or reduce physical contact between the photoresist layer and bump 134. The gap 170 provides physically separation between bump 134 and sloped surface 152 of photoresist layer 146 to reduce stress on bump 134 and conductive layer 142, particularly during thermal and other reliability testing. With less stress on bump 134 and conductive layer 142, there is less occurrence of cracking and other stress-induced damage on the interconnect structure between semiconductor die 124 and substrate 140 during the manufacturing process.

In FIG. 4k, an underfill material or molding compound 172 is deposited between semiconductor die 124 and substrate 140 using a paste printing, compressive molding, transfer molding, liquid encapsulant molding, vacuum lamination, spin coating, or other suitable applicator. Underfill material 172 can be polymer composite material, such as epoxy resin with filler, epoxy acrylate with filler, or polymer with proper filler.

An electrically conductive bump material is deposited over conductive layer 164 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 164 using a suitable attachment or bonding process. In one embodiment, the bump material is reflowed by heating the material above its melting point to form balls or bumps 174. In some applications, bumps 174 are reflowed a second time to improve electrical contact to conductive layer 164. Bumps 174 can also be compression bonded to conductive layer 164. Bumps 174 represent one type of interconnect structure that can be formed over conductive layer 174. The interconnect structure can also use stud bump, micro bump, or other electrical interconnect.

In summary, bumps 134 are formed over active surface 130 of semiconductor die 124. Conductive layer 142 is formed over substrate 140. Patterning layer 146 is formed over substrate 140 and conductive layer 142. Masking layer 148 has an opaque portion 148a and linear gradient contrast portion 148b over patterning layer 146. The linear gradient contrast portion 148b transitions from near transparent to near opaque. Patterning layer 146 is exposed to UV light through masking layer 148. Masking layer 148 is removed and a portion of patterning layer 146 is removed by an etching process to form an opening 150 having a sloped surface 152 to expose conductive layer 142. The sloped surface 152 in photoresist layer 146 can be linear, concave, or convex. The semiconductor die 124 is mounted to substrate 140 with bumps 134 electrically connected to conductive layer 142 and physically separated from photoresist layer 146 by nature of sloped surface 152. An underfill material 172 is deposited between semiconductor die 124 and substrate 140. Conductive layer 164 is formed over surface 166 of substrate 140 opposite conductive layer 142. The insulating layer 168 is formed over surface 166 of substrate 140.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die;
forming a plurality of bumps over a surface of the semiconductor die;
providing a substrate;
forming a first conductive layer over the substrate;
forming a patterning layer over the substrate and first conductive layer;
disposing a masking layer having an opaque portion and gradient contrast portion over the patterning layer;
exposing the patterning layer to ultraviolet light through the masking layer;
removing the masking layer;
removing a portion of the patterning layer to form an opening having a sloped surface to expose the first conductive layer; and
mounting the semiconductor die to the substrate with the bumps electrically connected to the first conductive layer and physically separated from the patterning layer.

2. The method of claim 1, wherein the gradient contrast portion transitions from near transparent to near opaque.

3. The method of claim 1, further including removing the portion of the patterning layer by an etching process.

4. The method of claim 1, wherein the sloped surface in the patterning layer is linear, concave, or convex.

5. The method of claim 1, further including depositing an underfill material between the semiconductor die and substrate.

6. The method of claim 1, further including:
forming a second conductive layer over a surface of the substrate opposite the first conductive layer; and
forming an insulating layer over the surface of the substrate.

7. A method of making a semiconductor device, comprising:
providing a semiconductor die;
forming an interconnect structure over a surface of the semiconductor die;
providing a substrate;
forming a first conductive layer over the substrate;
forming a patterning layer over the substrate and first conductive layer;
forming an opening having a sloped surface in the patterning layer to expose the first conductive layer; and
mounting the semiconductor die to the substrate with the interconnect structure electrically connected to the first conductive layer and separated from the patterning layer.

8. The method of claim 7, further including:
disposing a masking layer having an opaque portion and gradient contrast portion over the patterning layer;
exposing the patterning layer to ultraviolet light through the masking layer;
removing the masking layer; and
forming the opening having the sloped surface in the patterning layer to expose the first conductive layer.

9. The method of claim 8, wherein the gradient contrast portion transitions from near transparent to near opaque.

10. The method of claim 7, wherein the sloped surface in the patterning layer is linear, concave, or convex.

11. The method of claim 7, further including forming the sloped surface in patterning layer by laser direct ablation.

12. The method of claim 7, further including depositing an underfill material between the semiconductor die and substrate.

13. The method of claim 7, further including:
forming a second conductive layer over a surface of the substrate opposite the first conductive layer; and
forming an insulating layer over the surface of the substrate.

14. A method of making a semiconductor device, comprising:
providing a substrate;
forming a first conductive layer over the substrate;
forming a patterning layer over the substrate and first conductive layer; and
forming an opening having a sloped surface in the patterning layer to expose the first conductive layer.

15. The method of claim 14, further including mounting a semiconductor die to the substrate with an interconnect structure separated from the sloped surface of the patterning layer.

16. The method of claim 15, further including depositing an underfill material between the semiconductor die and substrate.

17. The method of claim 14, further including:
disposing a masking layer having an opaque portion and gradient contrast portion over the patterning layer;
exposing the patterning layer to ultraviolet light through the masking layer;
removing the masking layer; and
forming the opening having the sloped surface in the patterning layer to expose the first conductive layer.

18. The method of claim 17, wherein the gradient contrast portion transitions from near transparent to near opaque.

19. The method of claim 14, further including forming the sloped surface in patterning layer by laser direct ablation.

20. The method of claim 14, further including:
forming a second conductive layer over a surface of the substrate opposite the first conductive layer; and
forming an insulating layer over the surface of the substrate.

21. A semiconductor device, comprising:
a substrate;
a first conductive layer formed over the substrate;
a patterning layer formed over the substrate and first conductive layer; and
an opening having a sloped surface formed in the patterning layer to expose the first conductive layer.

22. The semiconductor device of claim 21, further including:
a semiconductor die; and
an interconnect structure disposed between the semiconductor die and substrate, the interconnect structure being separated from the sloped surface of the patterning layer.

23. The semiconductor device of claim 21, further including a masking layer having an opaque portion and gradient contrast portion disposed over the patterning layer.

24. The semiconductor device of claim 21, wherein the sloped surface in patterning layer is formed by laser direct ablation.

25. The semiconductor device of claim 21, further including:
a second conductive layer formed over a surface of the substrate opposite the first conductive layer; and
an insulating layer formed over the surface of the substrate.
